(19) United States
(12) Patent Application Publication
(10) Pub. No.: US 2015/0179764 A1
(43) Pub. Date: Jun. 25, 2015

(54) SEMICONDUCTOR DEVICE AND METHOD FOR MANUFACTURING SAME

(71) Applicant: KABUSHIKI KAISHA TOSHIBA, Tokyo (JP)

(72) Inventor: Hideki OKUMURA, Ishikawa-ken (JP)

(73) Assignee: KABUSHIKI KAISHA TOSHIBA, Tokyo (JP)

(21) Appl. No.: 14/639,428

(22) Filed: Mar. 5, 2015

Related U.S. Application Data
(62) Division of application No. 13/846,761, filed on Mar. 18, 2013.

(30) Foreign Application Priority Data
Jun. 13, 2012 (JP) 2012-134117

(51) Int. Cl. H01L 29/66; H01L 29/423; H01L 29/40

(52) U.S. Cl. CPC H01L 29/66734; H01L 29/407; H01L 29/4236; H01L 29/401

(57) ABSTRACT

A semiconductor device includes first to fourth semiconductor layers, a gate electrode, a field plate electrode, an insulating film, first and second main electrodes, and an insulating section. The second semiconductor layer has the first conductivity type and is provided on the first semiconductor layer. The third semiconductor layer has a second conductivity type and is provided on the second semiconductor layer. A concentration of impurity of the first conductivity type included in the third semiconductor layer is lower than the concentration of impurity of the first conductivity type included in the second semiconductor layer. The fourth semiconductor layer is provided on the third semiconductor layer. The gate electrode extends from the fourth semiconductor layer toward the second semiconductor layer. The field plate electrode is provided below the gate electrode.

### CROSS-REFERENCE TO RELATED APPLICATIONS

This application is a Divisional application of U.S. Ser. No. 13/846,761, which is based upon and claims the benefit of priority from the prior Japanese Patent Application No. 2012-134117, filed on Jun. 13, 2012; the entire contents of which are incorporated herein by reference.

### FIELD

Embodiments described herein relate generally to a semiconductor device and a method for manufacturing same.

### BACKGROUND

In the field of power electronics, semiconductor devices such as power MOSFET (metal oxide semiconductor field effect transistor) are used. In such semiconductor devices, the reduction of on-resistance is required.

### BRIEF DESCRIPTION OF THE DRAWINGS

FIG. 1A and FIG. 1B are schematic views illustrating a semiconductor device according to a first embodiment;

FIG. 2 is a graph illustrating the impurity concentration profile of the semiconductor device according to the first embodiment;

FIG. 3A to FIG. 3C are schematic sectional views illustrating the sequential steps of a method for manufacturing a semiconductor device according to the first embodiment;

FIG. 4A to FIG. 4C are schematic sectional views illustrating the sequential steps of a method for manufacturing a semiconductor device according to the first embodiment;

FIG. 5A to FIG. 5D are schematic sectional views illustrating the sequential steps of a method for manufacturing a semiconductor device according to the first embodiment;

FIG. 6A to FIG. 6C are schematic sectional views illustrating the sequential steps of a method for manufacturing a semiconductor device according to the first embodiment;

FIG. 7 is a flow chart illustrating the method for manufacturing a semiconductor device according to the first embodiment;

FIG. 8 is a schematic sectional view illustrating an alternative semiconductor device according to the first embodiment;

FIG. 9 is a schematic sectional view illustrating a semiconductor device according to a second embodiment;

FIG. 10A to FIG. 10D are schematic sectional views illustrating the sequential steps of a method for manufacturing a semiconductor device according to the second embodiment; and

FIG. 11A and FIG. 11B are schematic sectional views illustrating the sequential steps of an alternative method for manufacturing a semiconductor device according to the second embodiment.

### DETAILED DESCRIPTION

According to one embodiment, a semiconductor device includes a first semiconductor layer, a second semiconductor layer, a third semiconductor layer, a fourth semiconductor layer, a gate electrode, a field plate electrode, an insulating film, a first main electrode, a second main electrode, and an insulating section. The first semiconductor layer has a first conductivity type. The second semiconductor layer has the first conductivity type and is provided on the first semiconductor layer. A concentration of impurity of the first conductivity type included in the second semiconductor layer is lower than a concentration of impurity of the first conductivity type included in the first semiconductor layer. The third semiconductor layer has a second conductivity type and is provided on the second semiconductor layer. The third semiconductor layer has a first portion and a second portion surrounding the first portion in a plane perpendicular to stacking direction of the first semiconductor layer and the second semiconductor layer. A concentration of impurity of the first conductivity type included in the third semiconductor layer is lower than the concentration of impurity of the first conductivity type included in the second semiconductor layer. The fourth semiconductor layer has the first conductivity type and is provided on the first portion. The gate electrode extends from the fourth semiconductor layer toward the second semiconductor layer and has a lower end located in the second semiconductor layer. The field plate electrode is provided below the gate electrode and has a lower end located in the second semiconductor layer. The insulating film is provided between the gate electrode and the fourth semiconductor layer, between the gate electrode and the first portion, between the gate electrode and the second semiconductor layer, between the gate electrode and the field plate electrode, and between the field plate electrode and the second semiconductor layer. The first main electrode is electrically connected to the first semiconductor layer. The second main electrode is electrically connected to the third semiconductor layer and the fourth semiconductor layer. The insulating section is provided at least between the first portion and the second portion and is electrically insulating between the first portion and the second portion.

According to another embodiment, a method is disclosed for manufacturing a semiconductor device. The method can include forming a workpiece by forming a second semiconductor film on a major surface of a first semiconductor substrate having a first conductivity type, and by forming a third semiconductor film having a second conductivity type on the second semiconductor film by epitaxial growth. The second semiconductor film has a lower impurity concentration than the first semiconductor substrate. The workpiece includes the first semiconductor substrate, the second semiconductor film, and the third semiconductor film and having a device region and a termination region surrounding the device region in a plane parallel to the major surface. The method can include forming a gate trench and a termination trench. The gate trench penetrates through the third semiconductor film to part of the second semiconductor film in the device region. The termination trench penetrates through the third semiconductor film to part of the second semiconductor film at a boundary between the device region and the termination region. The method can include forming a first insulating layer on an inner wall surface of the gate trench and the termination trench. The method can include forming a field plate electrode in a portion of the gate trench below the third semiconductor film by embedding a conductive material in a remaining space in the gate trench. The method can include removing a portion of the first insulating layer above the field plate electrode. The method can include forming a second insulating layer above the field plate electrode in the gate trench and on the inner wall surface of the gate trench above the field plate electrode, and forming a gate electrode by embedding a conductive material in a remaining space in the gate trench. The method can include selectively doping an upper portion of the device region of the third semiconductor film with impurity of the first conductivity type.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the present specification and the drawings, components similar to those described previously with reference to earlier figures are labeled with like reference numerals, and the detailed description thereof is omitted appropriately.

### First Embodiment

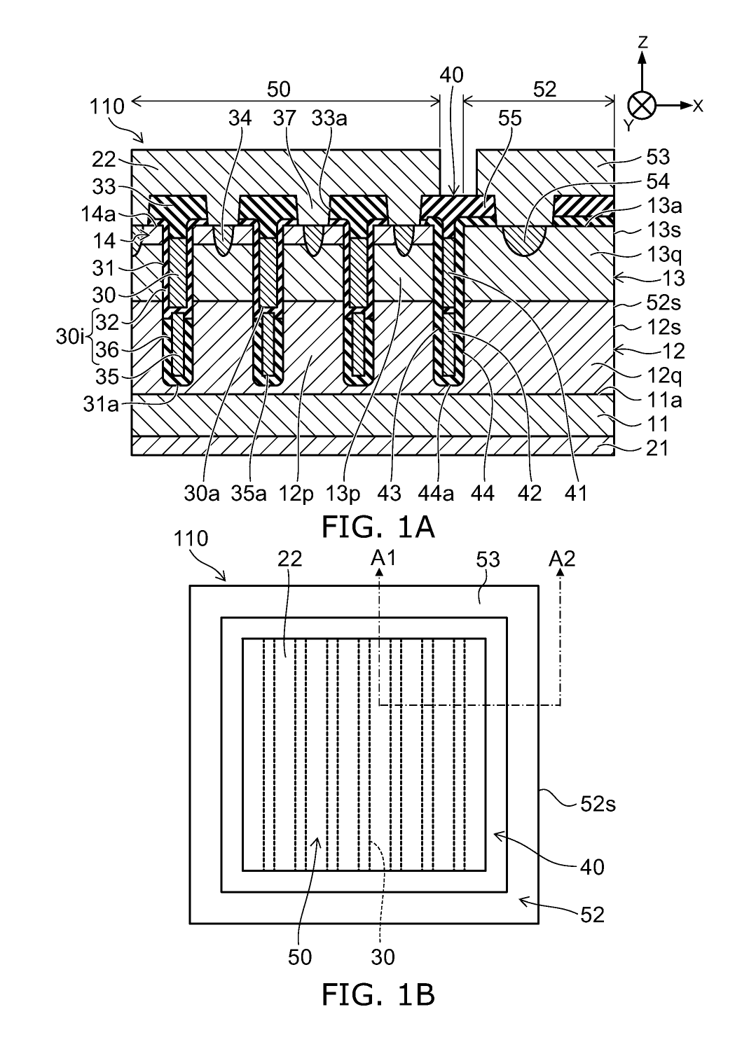

FIGS. 1A and 1B are schematic views illustrating a semiconductor device according to a first embodiment.

FIG. 1A is a schematic sectional view of the semiconductor device 110. FIG. 1B is a schematic plan view of the semiconductor device 110. For instance, FIG. 1A schematically shows a cross section taken along line A1-A2 of FIG. 1B.

As shown in FIGS. 1A and 1B, the semiconductor device 110 includes a first semiconductor layer 11, a second semiconductor layer 12, a third semiconductor layer 13, a fourth semiconductor layer 14, a first main electrode 21, a second main electrode 22, a gate electrode 30, a field plate electrode 35, an insulating film 30i, and an insulating section 40. For instance, the semiconductor device 110 is a MOSFET of the trench gate structure.

For instance, the first semiconductor layer 11 has a first conductivity type. The first semiconductor layer 11 has a major surface 11a. The first conductivity type may be either n-type or p-type. In the following description of this example, it is assumed that the first conductivity type is n-type. For instance, the first semiconductor layer 11 is an n+-drain layer. Here, the direction perpendicular to the major surface 11a is referred to as Z-axis direction. One direction perpendicular to the Z-axis direction is referred to as X-axis direction. The direction perpendicular to the Z-axis direction and the X-axis direction is referred to as Y-axis direction. The second semiconductor layer 12 is provided on the major surface 11a. For instance, the second semiconductor layer 12 has the first conductivity type. The impurity concentration of the second semiconductor layer 12 is lower than the impurity concentration of the first semiconductor layer 11. For instance, the second semiconductor layer 12 is an n−-drift layer.

The third semiconductor layer 13 is provided on the second semiconductor layer 12. For instance, the third semiconductor layer 13 has a second conductivity type. The second conductivity type is a conductivity type opposite to the first conductivity type. In this example, the second conductivity type is p-type. For instance, the third semiconductor layer 13 is a p-base layer. The third semiconductor layer 13 has a first portion 13p and a second portion 13q surrounding the first portion 13p. The second portion 13q surrounds the first portion 13p in a plane (X-Y plane) perpendicular to the stacking direction (Z-axis direction) of the first semiconductor layer 11 and the second semiconductor layer 12. In other words, the second portion 13q surrounds the first portion 13p about an axis along the Z-axis direction. The concentration of impurity of the first conductivity type included in the third semiconductor layer 13 is lower than the concentration of impurity included in the second semiconductor layer 12.

The fourth semiconductor layer 14 is provided on the first portion 13p. For instance, the fourth semiconductor layer 14 has the first conductivity type. For instance, the fourth semiconductor layer 14 is an n+-source layer. The position in the Z-axis direction of the upper surface 14a of the fourth semiconductor layer 14 is substantially equal to the position in the Z-axis direction of the upper surface 13a of the second portion 13q of the third semiconductor layer 13. For instance, the fourth semiconductor layer 14 is provided by ion implantation into the first portion 13p of a semiconductor layer constituting the third semiconductor layer 13. That is, the height (position) of the upper surface 14a is substantially equal to the height (position) of the upper surface 13a.

The first to fourth semiconductor layers 11-14 are made of e.g. silicon. For instance, the third semiconductor layer 13 is formed by epitaxial growth of silicon film doped with p-type impurity such as boron on the second semiconductor layer 12.

The semiconductor device 110 further includes a gate trench 31. For instance, the gate trench 31 extends from the upper surface 14a of the fourth semiconductor layer 14 toward the second semiconductor layer 12. The lower end 31a of the gate trench 31 is located in the second semiconductor layer 12. In this example, the position of the lower end 31a of the gate trench 31 is located above the major surface 11a. Alternatively, for instance, the gate trench 31 may penetrate through the second semiconductor layer 12 to the major surface 11a. The gate electrode 30 extends from the fourth semiconductor layer 14 toward the second semiconductor layer 12. The lower end 30a of the gate electrode 30 is located in the second semiconductor layer 12.

The insulating film 30i includes a gate insulating film 32 and a field plate insulating film 36.

For instance, the gate insulating film 32 is provided between the second semiconductor layer 12 and the gate electrode 30, between the third semiconductor layer 13 (first portion 13p) and the gate electrode 30, and between the fourth semiconductor layer 14 and the gate electrode 30. For instance, the gate electrode 30 is electrically insulated from the second semiconductor layer 12, the third semiconductor layer 13, and the fourth semiconductor layer 14 by the gate insulating film 32. The gate electrode 30 is made of e.g. polysilicon. The gate insulating film 32 is made of e.g. silicon oxide (e.g. SiO2).

For instance, the gate electrode 30, the gate trench 31, and the gate insulating film 32 extend along a first direction parallel to the major surface 11a. In this example, the first direction is the Y-axis direction. However, the first direction may be an arbitrary direction parallel to the major surface 11a.

The gate electrode 30, the gate trench 31, and the gate insulating film 32 can be provided in a plurality. For instance, the plurality of gate trenches 31 are arranged in a second direction parallel to the major surface 11a and perpendicular to the first direction. For instance, the spacing in the second direction of the plurality of gate trenches 31 is constant. In this example, the second direction is the X-axis direction. The plurality of gate electrodes 30 and the plurality of gate insulating films 32 are provided in the plurality of gate trenches 31, respectively. Alternatively, each of the gate electrode 30, the gate trench 31, and the gate insulating film 32 may be single.

The first main electrode 21 is provided below the first semiconductor layer 11. The first main electrode 21 is in contact with the first semiconductor layer 11. Thus, the first main electrode 21 is electrically connected to the first semiconductor layer 11. For instance, the first main electrode 21 is a drain electrode. The first main electrode 21 is made of e.g. a metal material such as V, Ni, Au, Ag, or Sn. The first main electrode 21 may be e.g. a stacked film including a plurality of stacked metal layers.

For instance, the second main electrode 22 is provided on the fourth semiconductor layer 14 and a plurality of gate electrodes 30. The second main electrode 22 is in contact with the fourth semiconductor layer 14. Thus, the second main electrode 22 is electrically connected to the fourth semiconductor layer 14. An interlayer insulating film 33 is provided between the second main electrode 22 and each of the plurality of gate electrodes 30. The interlayer insulating film 33 electrically insulates between the second main electrode 22 and the gate electrode 30. For instance, the second main electrode 22 is a source electrode. The second main electrode 22 is made of e.g. aluminum.

A first ohmic contact layer 34 is provided between each pair of the two nearest neighbor gate electrodes 30. For instance, the first ohmic contact layer 34 is provided at the center in the X-axis direction between the two nearest neighbor gate electrodes 30. In this example, the first ohmic contact layer 34 is provided also between the gate electrode 30 and the insulating section 40. The first ohmic contact layer 34 penetrates from the upper surface 14a of the fourth semiconductor layer 14 through the fourth semiconductor layer 14 to the third semiconductor layer 13. In this example, the first ohmic contact layer 34 extends along the Y-axis direction. For instance, the first ohmic contact layer 34 is provided parallel to the gate electrode 30. The first ohmic contact layer 34 has the second conductivity type. The impurity concentration of the first ohmic contact layer 34 is higher than the impurity concentration of the third semiconductor layer 13. For instance, the first ohmic contact layer 34 is a pt-layer. The impurity concentration of the first ohmic contact layer 34 is e.g. 1×10¹⁸ atoms/cm³ or more.

The interlayer insulating film 33 is provided with a plurality of openings 33a. The plurality of openings 33a expose the plurality of first ohmic contact layers 34, respectively. The portion of the second main electrode 22 inserted into the opening 33a constitutes a contact section 37. The second main electrode 22 is in ohmic contact with the plurality of first ohmic contact layers 34 via a plurality of contact sections 37, respectively. The second main electrode 22 is electrically connected to the third semiconductor layer 13 partly exposed at the upper surface 14a of the fourth semiconductor layer 14 through the first ohmic contact layer 34. The first ohmic contact layer 34 electrically connects between the second main electrode 22 and the third semiconductor layer 13. Thus, the first ohmic contact layer 34 fixes the potential of the third semiconductor layer 13 to the potential of the second main electrode 22. This stabilizes the threshold voltage of the semiconductor device 110. Furthermore, the first ohmic contact layer 34 serves as a bypass for passing minority carriers (e.g., holes) from the third semiconductor layer 13 to the second main electrode 22 when the gate voltage is switched from ON to OFF. This can improve e.g. the withstand capability for avalanche breakdown.

The field plate electrode 35 is provided below the gate electrode 30 in the gate trench 31. The lower end 35a of the field plate electrode 35 is located in the second semiconductor layer 12. The field plate insulating film 36 is provided between the second semiconductor layer 12 and the field plate electrode 35. The field plate insulating film 36 electrically insulates between the second semiconductor layer 12 and the field plate electrode 35. The gate insulating film 32 is provided between the field plate electrode 35 and the gate electrode 30. The field plate electrode 35 is electrically insulated from the gate electrode 30 by the gate insulating film 32. In the gate insulating film 32 and the field plate insulating film 36 included in the insulating film 30i, there are cases where a boundary is observed between the gate insulating film 32 and the field plate insulating film 36, and cases where no boundary is observed therebetween.

The field plate electrode 35 is electrically connected to the second main electrode 22. For instance, the field plate electrode 35 is set to the source potential. Each of the field plate electrode 35 and the field plate insulating film 36 can be provided in a plurality. The plurality of field plate electrodes 35 and the plurality of field plate insulating films 36 are provided in the plurality of gate trenches 31, respectively. For instance, the field plate electrode 35 and the field plate insulating film 36 extend along the Y-axis direction. For instance, the length in the Y-axis direction of the field plate electrode 35 and the length in the Y-axis direction of the field plate insulating film 36 are substantially equal to the length in the Y-axis direction of the gate electrode 30. The field plate electrode 35 and the field plate insulating film 36 are provided below the gate electrode 30 and extend in the Y-axis direction along the gate electrode 30. The thickness of the field plate insulating film 36 (the thickness along the X-axis direction) is thicker than the thickness of the gate insulating film 32 (the thickness along the X-axis direction). For instance, the width along the X-axis direction of the field plate electrode 35 is wider than the width along the X-axis direction of the gate electrode 30. The field plate electrode 35 reduces the gate-drain capacitance. The field plate electrode 35 is electrically connected to the second main electrode 22 (source electrode) or the gate electrode 30. The field plate electrode 35 has the effect of pushing down the source potential or the gate potential to the lower end 31a of the gate trench 31. Consequently, the field plate electrode 35 facilitates spreading the depletion layer formed in the second semiconductor layer 12. Thus, for instance, the field plate electrode 35 increases the breakdown voltage of the semiconductor device 110. The field plate electrode 35 is made of e.g. polysilicon. The field plate insulating film 36 is made of e.g. SiO2.

In the semiconductor device 110, for instance, the gate electrode 30 is applied with a positive voltage, the first main electrode 21 is applied with a positive voltage, and the second main electrode 22 is grounded. Thus, a current flows between the first main electrode 21 and the second main electrode 22.

Upon application of voltage to the gate electrode 30, the first main electrode 21, and the second main electrode 22, an inversion channel is formed in a region of the third semiconductor layer 13 near the gate insulating film 32. For instance, the current flows from the first main electrode 21 through the first semiconductor layer 11, the second semiconductor layer 12, the inversion channel, and the fourth semiconductor layer 14 to the second main electrode 22.

The semiconductor device 110 has a device region 50 provided with a plurality of gate electrodes 30, and a termination region 52 surrounding the outer periphery of the device region 50. The device region 50 corresponds to the first portion 13p of the third semiconductor layer 13. The termination region 52 corresponds to the second portion 13q of the third semiconductor layer 13. In the device region 50, the second main electrode 22 is opposed to a plurality of gate electrodes 30. In the device region 50, the first main electrode 21 and the second main electrode 22 are opposed to each other. The device region 50 is a region for passing a current between the first main electrode 21 and the second main electrode 22 in response to application of voltage to the first main electrode 21 and the second main electrode 22.

In this example, the third semiconductor layer 13 extends to the outer peripheral edge 52s of the termination region 52. The second semiconductor layer 12 has a side surface 12s (first side surface) along the stacking direction (Z-axis direction). The second portion 13q of the third semiconductor layer 13 has a side surface 13s (second side surface) along the stacking direction. The side surface 13s at the outer edge of the third semiconductor layer 13 is located in a plane including the side surface 12s at the outer edge of the second semiconductor layer 12. For instance, the side surface 13s is located in the same plane as the side surface 12s. For instance, the outer peripheral edge 52s is a dicing line. In this example, the fourth semiconductor layer 14 does not extend to the outer peripheral edge 52s of the termination region 52.

However, the fourth semiconductor layer 14 may extend to the outer peripheral edge 52s of the termination region 52. That is, the fourth semiconductor layer 14 may be further provided on the third semiconductor layer 13 (on the first portion 13p and the second portion 13q).

The insulating section 40 is provided between the device region 50 and the termination region 52. The insulating section 40 is shaped like e.g. a ring surrounding the device region 50. For instance, the insulating section 40 includes a first termination electrode 41, a second termination electrode 42, a termination insulating film 43, and a termination trench 44. For instance, the termination trench 44 penetrates from the upper surface 14a side of the fourth semiconductor layer 14 through the fourth semiconductor layer 14 and the third semiconductor layer 13 and partly penetrates into the second semiconductor layer 12. In this example, the position of the lower end 44a of the termination trench 44 is located slightly above the major surface 11a. The position in the Z-axis direction of the lower end 44a of the termination trench 44 is substantially equal to the position in the Z-axis direction of the lower end 31a of the gate trench 31. The termination trench 44 may penetrate through the second semiconductor layer 12 to the major surface 11a. The position in the Z-axis direction of the lower end 44a of the termination trench 44 may be different from the position in the Z-axis direction of the lower end 31a of the gate trench 31.

The first termination electrode 41 is provided inside the termination trench 44 via the termination insulating film 43. The termination insulating film 43 is provided between the second semiconductor layer 12 and the first termination electrode 41, between the third semiconductor layer 13 and the first termination electrode 41, and between the fourth semiconductor layer 14 and the first termination electrode 41. The first termination electrode 41 is electrically insulated from the second semiconductor layer 12, the third semiconductor layer 13, and the fourth semiconductor layer 14 by the termination insulating film 43.

The second termination electrode 42 is provided below the first termination electrode 41 inside the termination trench 44. The termination insulating film 43 is provided also between the second termination electrode 42 and the second semiconductor layer 12. The second termination electrode 42 is electrically insulated from the second semiconductor layer 12 by the termination insulating film 43. The termination insulating film 43 is provided between the first termination electrode 41 and the second termination electrode 42. The second termination electrode 42 is separated from the first termination electrode 41 by the termination insulating film 43.

The first termination electrode 41 and the second termination electrode 42 are made of e.g. polysilicon. The termination insulating film 43 is made of e.g. silicon oxide (SiO2). For instance, the first termination electrode 41 and the second termination electrode 42 are electrically connected to the second main electrode 22. For instance, the first termination electrode 41 and the second termination electrode 42 are set to the source potential. The first termination electrode 41 may be electrically connected to the gate electrode 30. This facilitates depleting the second semiconductor layer 12 and the third semiconductor layer 13 adjacent to the insulating section 40. The first portion 13p is a portion of the third semiconductor layer 13 provided in the device region 50. The second portion 13q is a portion of the third semiconductor layer 13 provided in the termination region 52. The insulating section 40 is provided between the first portion 13p and the second portion 13q. The insulating section 40 electrically insulates at least between the first portion 13p and the second portion 13q.

The portion of the second semiconductor layer 12 provided in the device region 50 is referred to as third portion 12p. The portion of the second semiconductor layer 12 provided in the termination region 52 is referred to as fourth portion 12q. In the termination region 52, the fourth portion 12q is made substantially equipotential with the second portion 13q by the current flowing through the crushed layer at the outer peripheral edge 52s of the chip. The side surface 12s and the side surface 13s are crushed layers. The insulating section 40 maintains the potential difference between the first portion 13p and the third portion 12p at an appropriate level. Furthermore, for instance, the insulating section 40 suppresses that the depletion layer formed upon voltage application reaches the outer peripheral edge 52s. Thus, a depletion layer is appropriately formed in the first portion 13p and the third portion 12p. Here, alternatively, the insulating section 40 may be formed from only the termination insulating film 43 without being provided with the first termination electrode 41 and the second termination electrode 42. The insulating section 40 only needs to have at least the function of electrically insulating between the first portion 13p and the second portion 13q.

On the second portion 13q, an outer peripheral electrode 53 is provided. The outer peripheral electrode 53 is shaped like e.g. a ring surrounding the device region 50. The outer peripheral electrode 53 is electrically connected to the first main electrode 21. For instance, the outer peripheral electrode 53 is set to the drain potential. For instance, the outer peripheral electrode 53 is in contact with the second portion 13q. The outer peripheral electrode 53 is electrically connected to the second portion 13q.

In the second portion 13q, a second ohmic contact layer 54 is provided. The second ohmic contact layer 54 is provided in the upper surface 13a of the second portion 13q of the third semiconductor layer 13. The second ohmic contact layer 54 is shaped like e.g. a ring along the insulating section 40. For instance, the second ohmic contact layer 54 is a pt-layer designed to be of the same second conductivity type as the third semiconductor layer 13 and to have a higher concentration than the third semiconductor layer 13. The second ohmic contact layer 54 is in ohmic contact with the outer peripheral electrode 53. Thus, the second portion 13q is electrically connected to the first main electrode 21 via the outer peripheral electrode 53 and the second ohmic contact layer 54. For instance, the second portion 13q is set to the drain potential. The second portion 13q is made substantially equipotential with the fourth portion 12q via the leakage current flowing at the outer peripheral edge 52s. The fourth portion 12q is set to the drain potential. This can increase the breakdown voltage of the semiconductor device 110.

On the first termination electrode 41, for instance, an interlayer insulating film 55 is provided. The interlayer insulating film 55 is provided between the first termination electrode 41 and the second main electrode 22, and between the first termination electrode 41 and the outer peripheral electrode 53. The interlayer insulating film 55 electrically insulates between the first termination electrode 41 and the second main electrode 22. The interlayer insulating film 55 electrically insulates between the first termination electrode 41 and the outer peripheral electrode 53.

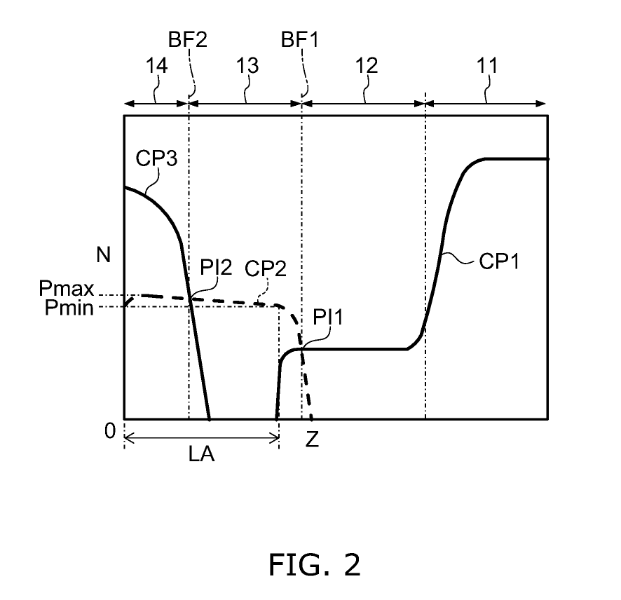

FIG. 2 is a graph illustrating the impurity concentration profile of the semiconductor device according to the first embodiment.

FIG. 2 is a graph illustrating the impurity concentration of the first to fourth semiconductor layers 11-14 of the semiconductor device 110.

In FIG. 2, the horizontal axis represents position Z in the Z-axis direction (depth direction). The vertical axis represents impurity concentration N. On the horizontal axis, the origin 0 represents the position of the upper surface 14a of the fourth semiconductor layer 14.

In FIG. 2, the solid line represents n-type impurity concentration. The dashed line represents p-type impurity concentration.

As shown in FIG. 2, the concentration of n-type impurity included in the third semiconductor layer 13 is lower than the concentration of n-type impurity included in the second semiconductor layer 12. The concentration of n-type impurity included in the third semiconductor layer 13 is lower than the concentration of n-type impurity included in the fourth semiconductor layer 14. The region having a low rate of change of p-type impurity concentration with respect to the Z-axis direction is referred to as low rate-of-change region LA. The low rate-of-change region LA is provided in the third semiconductor layer 13. In this example, the low rate-of-change region LA extends to the fourth semiconductor layer 14. The p-type impurity concentration in the low rate-of-change region LA is substantially constant. That is, the p-type impurity concentration in the semiconductor device 110 is substantially constant in the depth direction from the upper surface 14a of the fourth semiconductor layer 14 toward the third semiconductor layer 13.

For instance, the impurity concentration profile of the semiconductor device 110 shown in FIG. 2 can be formed by forming the third semiconductor layer 13 on the second semiconductor layer 12 by epitaxial growth and forming the fourth semiconductor layer 14 on the third semiconductor layer 13 by ion implantation and thermal diffusion. The profile representing the n-type impurity concentration on the side of the first semiconductor layer 11 and the second semiconductor layer 12 is referred to as first profile CP1. The profile representing the p-type impurity concentration of the third semiconductor layer 13 is referred to as second profile CP2. The intersection point of the first profile CP1 and the second profile CP2 is referred to as intersection point PI1. The profile representing the n-type impurity concentration on the fourth semiconductor layer 14 side is referred to as third profile CP3. The intersection point of the third profile CP3 and the second profile CP2 is referred to as intersection point PI2. In this example, the interface BF1 between the second semiconductor layer 12 and the third semiconductor layer 13 is e.g. an X-Y plane at the position in the Z-axis direction of the intersection point PI1. The interface BF2 between the third semiconductor layer 13 and the fourth semiconductor layer 14 is e.g. an X-Y plane at the position in the Z-axis direction of the intersection point PI2.

The n-type impurity of the first semiconductor layer 11 is e.g. at least one of phosphorus (P), arsenic (As), and antimony (Sb). The n-type impurity of the second semiconductor layer 12 is e.g. phosphorus. The p-type impurity of the third semiconductor layer 13 is e.g. boron (B). The n-type impurity of the fourth semiconductor layer 14 is e.g. at least one of phosphorus and arsenic.

The concentration of n-type impurity included in the first semiconductor layer 11 is e.g. 1×10¹⁹ atoms/cm³ or more. The optimal value of the impurity concentration depends on the breakdown voltage. Here, the specification based on a breakdown voltage of 30 V is taken as an example. Then, the concentration of n-type impurity included in the second semiconductor layer 12 is e.g. 1×10¹⁶ atoms/cm³ or more and 1×10¹⁷ atoms/cm³ or less. The concentration of p-type impurity included in the third semiconductor layer 13 is e.g. 5×10¹⁶ atoms/cm³ or more and less than 1×10¹⁸ atoms/cm³. The concentration of n-type impurity included in the fourth semiconductor layer 14 is e.g. 1×10¹⁸ atoms/cm³ or more. The concentration of n-type impurity included in the first semiconductor layer 11 and the fourth semiconductor layer 14 is e.g. 1×10¹⁸ atoms/cm³ or less. However, the upper limit of the concentration of n-type impurity included in the first semiconductor layer 11 and the fourth semiconductor layer 14 may be arbitrary. The concentration of n-type impurity included in the third semiconductor layer 13 is e.g. 5×10¹⁵ atoms/cm³ or less. Here, for instance, the impurity concentration of the first to fourth semiconductor layers 11-14 is the average concentration over the positions in the Z-axis direction.

The maximum concentration in the low rate-of-change region LA is denoted by Pmax. The minimum concentration in the low rate-of-change region LA is denoted by Pmin. Then, the ratio Pmax/Pmin of Pmax to Pmin is 5 or less. In the low rate-of-change region LA, the impurity concentration being substantially constant refers to the state in which the ratio Pmax/Pmin is 5 or less. For instance, the ratio Pmax/Pmin is set to 3 or less. Thus, for instance, the on-resistance can be reduced. Immediately after the formation of the third semiconductor layer 13, the ratio Pmax/Pmin is substantially 1. For instance, by heat treatment and the like performed after the formation of the third semiconductor layer 13, the n-type impurity included in the third semiconductor layer 13 diffuses into the second semiconductor layer 12. Thus, the ratio Pmax/Pmin gradually increases with the heat treatment and the like after the formation of the third semiconductor layer 13. In the second profile CP2, the change of concentration associated with the diffusion and the like becomes greater toward the interface BF1. Accordingly, the range of ±50 nm in the Z-axis direction from the interface BF1 is not included in the low rate-of-change region LA. Thus, the low rate-of-change region LA can be appropriately configured. There is a semiconductor device (hereinafter referred to as reference example) in which the third semiconductor layer 13 is formed by ion implantation and thermal diffusion. In the configuration of the reference example, the p-type impurity concentration gradually decreases in the depth direction from the upper surface 14a of the fourth semiconductor layer 14 toward the third semiconductor layer 13. Thus, in the configuration of the reference example, if the thickness (length along the Z-axis direction) of the third semiconductor layer 13 is thinned to realize a shorter channel, variation in threshold voltage among a plurality of gate electrodes 30 becomes larger. Furthermore, if the channel is made shorter in the configuration of the reference example, the depletion layer extending toward the second main electrode 22 from the junction interface between the second semiconductor layer 12 and the third semiconductor layer 13 easily reaches the second main electrode 22. That is, this results in punch-through, and hence the desired breakdown voltage is not obtained. Thus, in the configuration of the reference example, a shorter channel is difficult to realize.

Furthermore, in the configuration of the reference example, the third semiconductor layer 13 also includes n-type impurity at substantially the same concentration as the second semiconductor layer 12. Thus, in forming the third semiconductor layer 13 in the configuration of the reference example, more p-type impurity needs to be implanted than n-type impurity. Recently, from the requirements of the reduction of on-resistance and the miniaturization of the gate electrode 30, there has been a growing demand for increasing the n-type impurity concentration of the second semiconductor layer 12. However, in the configuration of the reference example, if the n-type impurity concentration of the second semiconductor layer 12 is increased, the p-type impurity concentration of the third semiconductor layer 13 needs to be increased accordingly. If the p-type impurity concentration of the third semiconductor layer 13 is increased, the mobility of electrons and holes in the third semiconductor layer 13 decreases. This results in increasing the on-resistance. Thus, in the configuration of the reference example, the on-resistance is difficult to reduce.

In the semiconductor device 110 according to the embodiment, the low rate-of-change region LA, which is a region having a low rate of change of p-type impurity concentration with respect to the Z-axis direction, is provided in the third semiconductor layer 13. Thus, for instance, even when the thickness of the third semiconductor layer 13 is thinned to realize a shorter channel, it is possible to suppress variation in threshold voltage among a plurality of gate electrodes 30 and extension of the depletion layer to the second main electrode 22. For instance, in the semiconductor device 110, a shorter channel is realized more easily than in the configuration of the reference example.

In the embodiment, the concentration of n-type impurity included in the third semiconductor layer 13 is lower than the concentration of n-type impurity included in the second semiconductor layer 12. In the embodiment, the concentration of p-type impurity included in the third semiconductor layer 13 can be made lower than in the configuration of the reference example. For instance, this can suppress the decrease of mobility, and can achieve a lower on-resistance than in the configuration of the reference example.

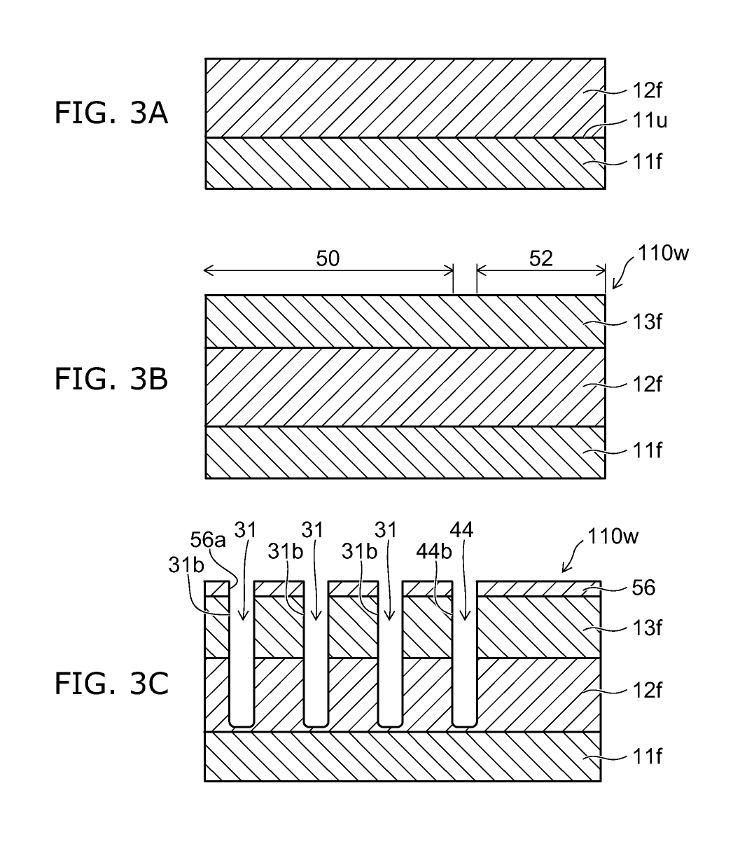

FIGS. 3A to 3C, 4A to 4C, 5A to 5D, and 6A to 6C are schematic sectional views illustrating the sequential steps of a method for manufacturing a semiconductor device according to the first embodiment.

As shown in FIG. 3A, on a major surface 11u of a first semiconductor substrate 11f constituting a first semiconductor layer 11, a second semiconductor film 12f constituting a second semiconductor layer 12 is formed. For instance, the second semiconductor film 12f is formed by epitaxial growth. Alternatively, the second semiconductor film 12f may be formed by e.g. ion implantation and thermal diffusion.

As shown in FIG. 3B, on the second semiconductor film 12f, a third semiconductor film 13f constituting a third semiconductor layer 13 is formed. For instance, the third semiconductor film 13f is formed by epitaxial growth. Thus, a workpiece 110w is formed. The workpiece 110w includes the first semiconductor substrate 11f, the second semiconductor film 12f, and the third semiconductor film 13f. The workpiece 110w has a device region 50 and a termination region 52 surrounding the device region 50 in a plane parallel to the major surface 11u.

As shown in FIG. 3C, on the third semiconductor film 13f, a mask 56 is formed. The mask 56 is provided with a pattern 56a corresponding to a plurality of gate trenches 31 and a termination trench 44. Anisotropic etching is performed on the workpiece 110w to transfer the pattern 56a of the mask 56 to the workpiece 110w. Thus, in the device region 50, a plurality of gate trenches 31 are formed in the workpiece 110w. Furthermore, at the boundary between the device region 50 and the termination region 52, a termination trench 44 is formed in the workpiece 110w. The termination trench 44 is formed simultaneously with the plurality of gate trenches 31. Alternatively, the termination trench 44 may be formed independently of the plurality of gate trenches 31.

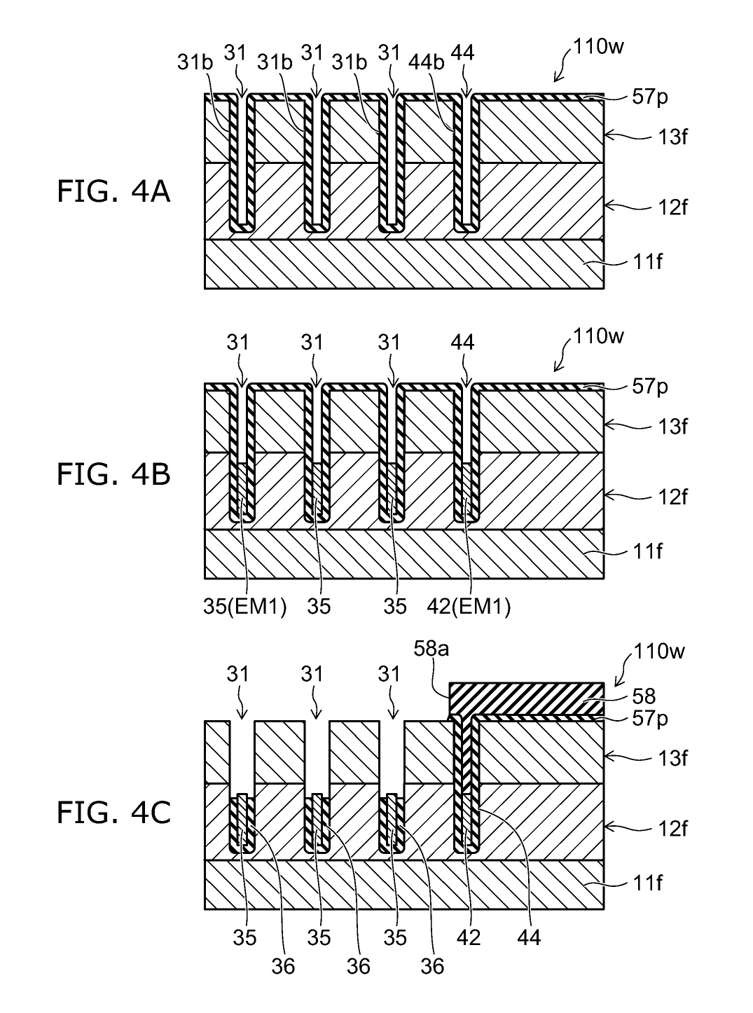

As shown in FIG. 4A, on the workpiece 110w, a first insulating layer 57p constituting a field plate insulating film 36 and a termination insulating film 43 is formed. The first insulating layer 57p is formed at least on the inner wall surface 31b of the gate trench 31 and on the inner wall surface 44b of the termination trench 44.

As shown in FIG. 4B, a conductive material EM1 is embedded in the remaining space in the gate trench 31 to form a field plate electrode 35 in the portion of the gate trench 31 below the third semiconductor film 13f. The conductive material EM1 is embedded in the remaining space in the termination trench 44 to form a second termination electrode 42 in the portion of the termination trench 44 below the third semiconductor film 13f. In forming the field plate electrode 35 and the second termination electrode 42, after embedding the conductive material EM1, etching of the conductive material EM1 may be performed. The second termination electrode 42 may be formed independently of the field plate electrode 35. As shown in FIG. 4C, a mask 58 is formed on the first insulating layer 57p. For instance, by etching, the pattern 58a of the mask 58 is transferred to remove the portion of the first insulating layer 57p above the field plate electrode 35. Thus, a field plate insulating film 36 is formed from the first insulating layer 57p.

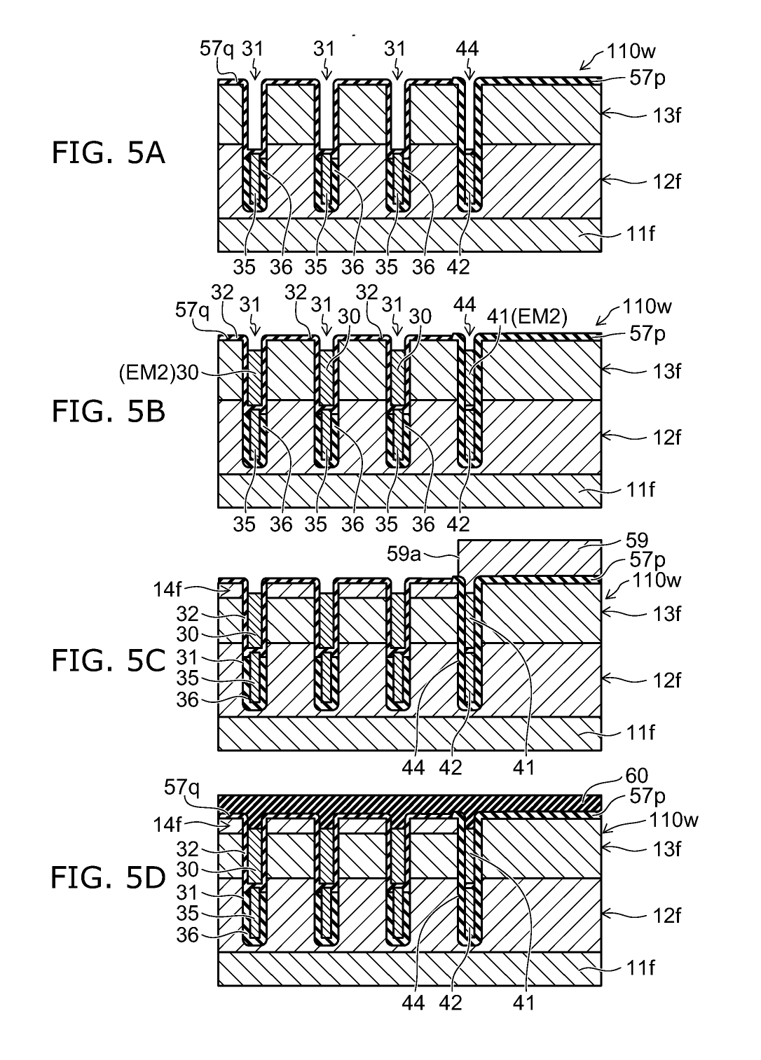

As shown in FIG. 5A, a second insulating layer 57q is formed above the field plate electrode 35 in the gate trench 31, and on the inner wall surface 31b of the gate trench 31 above the field plate electrode 35.

As shown in FIG. 5B, a conductive material EM2 is embedded in the remaining space in the gate trench 31. Thus, a gate electrode 30 is formed above the field plate electrode 35 in the gate trench 31 via the gate insulating film 32. The conductive material EM2 is embedded in the remaining space in the termination trench 44 to form a first termination electrode 41 above the second termination electrode 42.

As shown in FIG. 5C, a mask 59 is formed on the workpiece 110w. The mask 59 is provided with a pattern 59a for exposing the portion of the device region 50 in the third semiconductor film 13f. The upper portion of the device region 50 of the third semiconductor film 13f is selectively doped with impurity of the first conductivity type. Thus, a fourth semiconductor film 14f is formed in the upper portion of the third semiconductor film 13f.

As shown in FIG. 5D, the mask 59 is removed. Then, an interlayer insulating layer 60 is formed on the workpiece 110w. The interlayer insulating layer 60 is formed by using e.g. CVD processing.

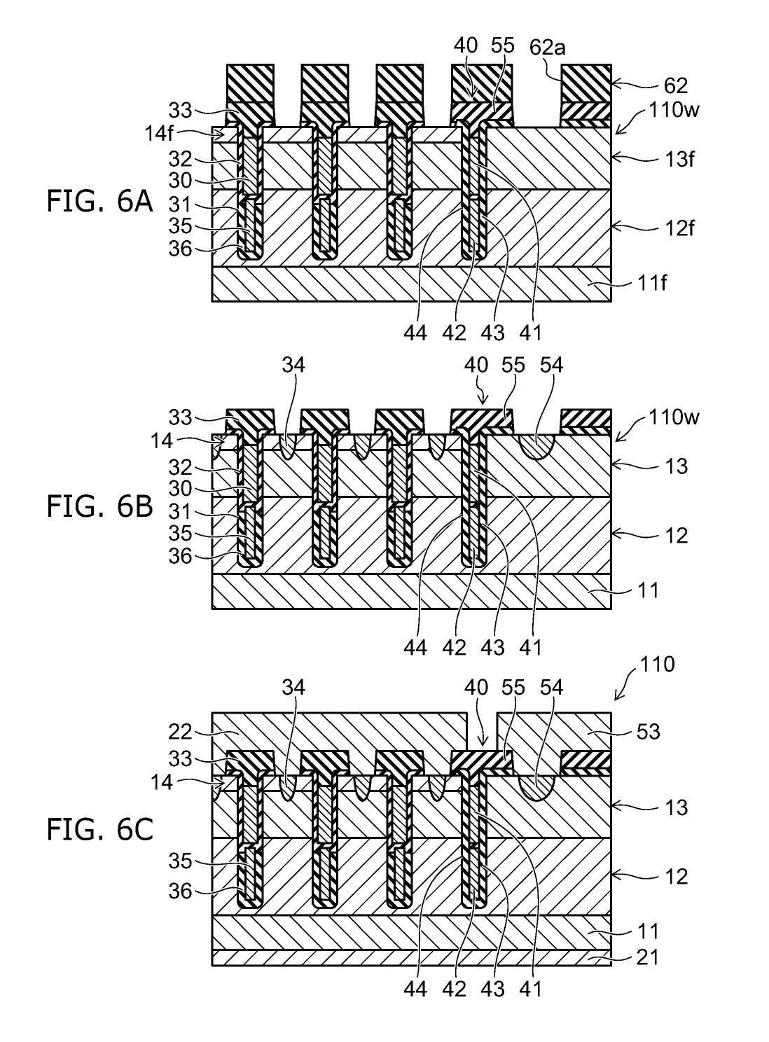

As shown in FIG. 6A, a mask 62 is formed on the interlayer insulating layer 60. For instance, by etching, the pattern 62a of the mask 62 is transferred to remove part of the first insulating layer 57p, part of the second insulating layer 57q, and part of the interlayer insulating layer 60. Thus, a termination insulating film 43 is formed from the first insulating layer 57p. A gate insulating film 32 is formed from the second insulating layer 57q. An interlayer insulating film 33 and an interlayer insulating film 55 are formed from the interlayer insulating layer 60. Thus, an insulating section 40 is formed.

As shown in FIG. 6B, a plurality of first ohmic contact layers 34 are formed in the portion of the device region 50 of the fourth semiconductor film 14f. A second ohmic contact layer 54 is formed in the portion of the termination region 52 of the fourth semiconductor film 14f. The second ohmic contact layer 54 is formed simultaneously with the plurality of first ohmic contact layers 34. Alternatively, the second ohmic contact layer 54 may be formed independently of the plurality of first ohmic contact layers 34. For instance, the plurality of first ohmic contact layers 34 and the second ohmic contact layer 54 are formed by photolithography processing and ion implantation. Thus, a first semiconductor layer 11 is formed from the first semiconductor film 11f. A second semiconductor layer 12 is formed from the second semiconductor film 12f. A third semiconductor layer 13 is formed from the third semiconductor film 13f. A fourth semiconductor layer 14 is formed from the fourth semiconductor film 14f.

As shown in FIG. 6C, a first main electrode 21 is formed below the first semiconductor layer 11. A second main electrode 22 is formed on the fourth semiconductor layer 14. An outer peripheral electrode 53 is formed on the second portion 13q of the third semiconductor layer 13. The outer peripheral electrode 53 may be formed simultaneously with, or independently of, the second main electrode 22. For instance, the first main electrode 21, the second main electrode 22, and the outer peripheral electrode 53 are formed by sputtering, evaporation and the like.

Thus, the semiconductor device 110 is completed.

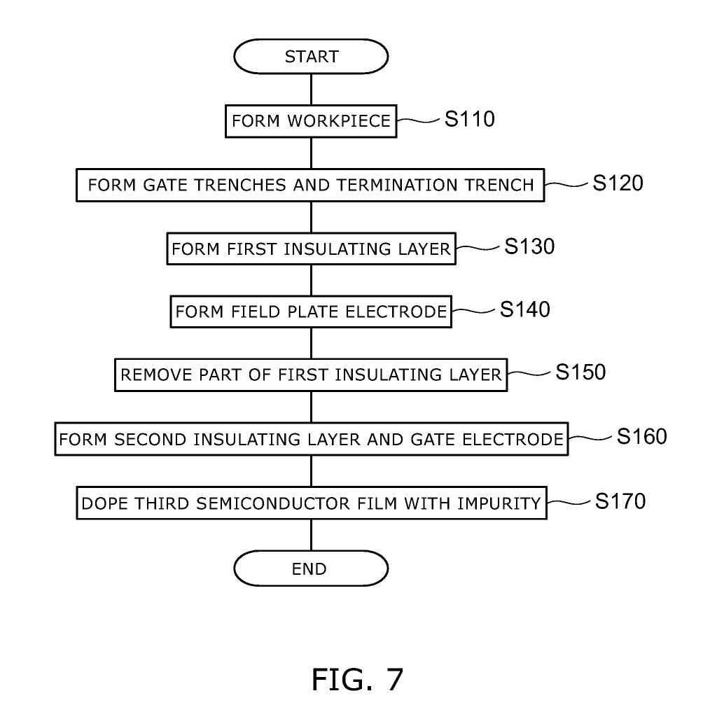

FIG. 7 is a flow chart illustrating the method for manufacturing a semiconductor device according to the first embodiment.

As shown in FIG. 7, the method for manufacturing the semiconductor device 110 according to the embodiment includes the step S110 of forming a workpiece 110w, the step S120 of forming gate trenches 31 and a termination trench 44, the step S130 of forming a first insulating layer 57p, the step S140 of forming a field plate electrode 35, the step S150 of removing part of the first insulating layer 57p, the step S160 of forming a second insulating layer 57q and a gate electrode 30, and the step S170 of doping the third semiconductor film 13f with impurity.

In the step S110, for instance, the processing described with reference to FIGS. 3A and 3B is performed. In the step S120, for instance, the processing described with reference to FIG. 3C is performed. In the step S130, for instance, the processing described with reference to FIG. 4A is performed. In the step S140, for instance, the processing described with reference to FIG. 4B is performed. In the step S150, for instance, the processing described with reference to FIG. 4C is performed. In the step S160, for instance, the processing described with reference to FIGS. 5A and 5B is performed. In the step S170, for instance, the processing described with reference to FIG. 5C is performed.

Thus, the semiconductor device 110 having low on-resistance is manufactured.

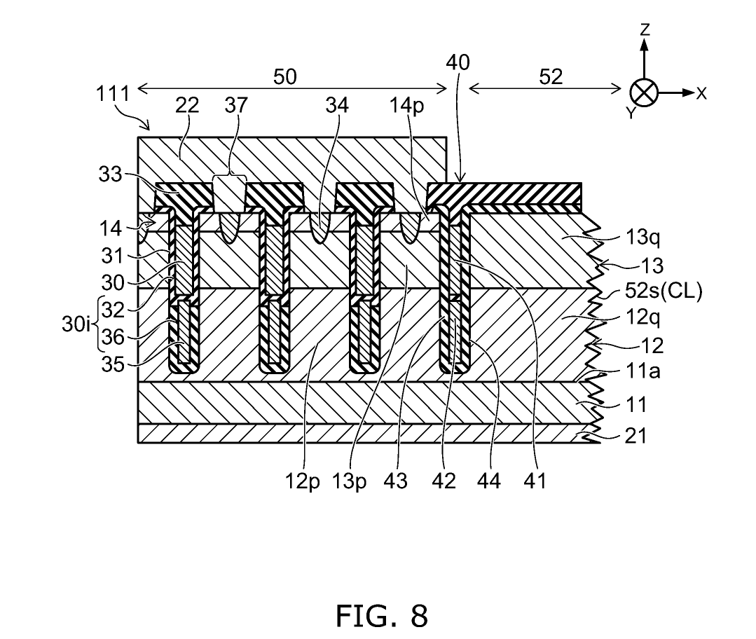

FIG. 8 is a schematic sectional view illustrating an alternative semiconductor device according to the first embodiment.

As shown in FIG. 8, in the semiconductor device 111, the outer peripheral electrode 53 is omitted. In the semiconductor device 111, for instance, the second portion 13q of the third semiconductor layer 13 is set to a floating potential. Thus, the potential of the second portion 13q may be a floating potential.

For instance, the semiconductor device 111 is formed by dicing a wafer constituting the semiconductor device 111. The outer peripheral edge 52s (side surface) of the semiconductor device 111 is a crushed layer CL formed by dicing. In this case, for instance, leakage current flows more easily between the second portion 13q and the fourth portion 12q. Thus, for instance, the potential of the second portion 13q is set more easily to the same potential as the potential of the fourth portion 12q. This stabilizes the operation.

### Second Embodiment

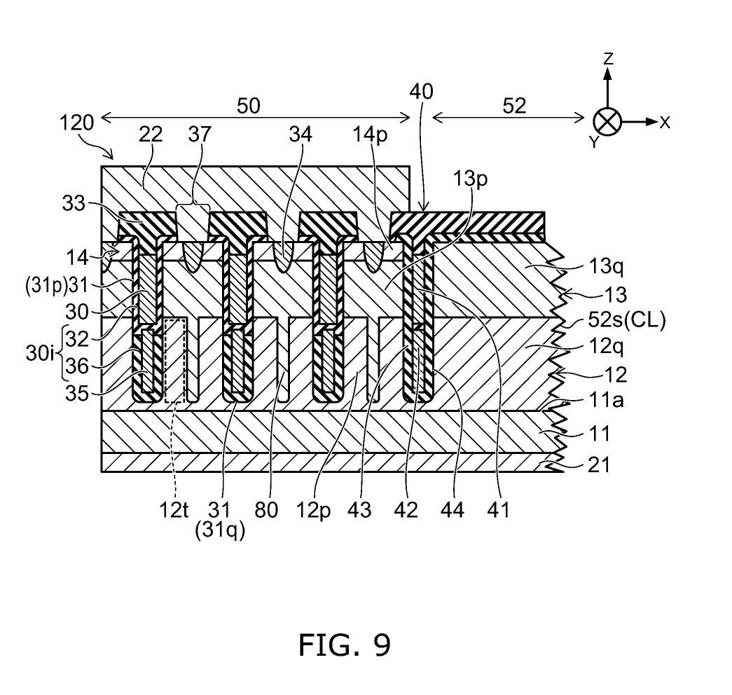

FIG. 9 is a schematic sectional view illustrating a semiconductor device according to a second embodiment.

As shown in FIG. 9, the third semiconductor layer 13 of the semiconductor device 120 has a pillar section 80 extending from the first portion 13p toward the first semiconductor layer 11. The pillar section 80 is provided in a plurality in the third semiconductor layer 13. The plurality of pillar sections 80 are each provided between the two nearest neighbor gate trenches 31. The plurality of gate trenches 31 include a first gate trench 31p extending along the Y-axis direction and spaced from the pillar section 80 in the X-axis direction, and a second gate trench 31q extending along the Y-axis direction and spaced from the pillar section 80 on the opposite side from the first gate trench 31p in the X-axis direction. The pillar section 80 is placed between the first gate trench 31p and the second gate trench 31q. For instance, the pillar section 80 is provided at the center between the first gate trench 31p and the second gate trench 31q. In this example, the pillar section 80 is provided also between the gate trench 31 and the insulating section 40. The pillar section 80 extends along the Y-axis direction. The pillar section 80 is provided parallel to the gate electrode 30 and the field plate electrode 35. The concentration of p-type impurity included in the pillar section 80 is less than or equal to the concentration of n-type impurity included in the second semiconductor layer 12. The effective dose amount (in units of atoms/cm²) of impurity of the second conductivity type per unit area of the pillar section 80 in the X-Y plane is denoted by N1. The region of the second semiconductor layer 12 opposed to the pillar section 80 in the X-axis direction is referred to as opposed region 12t. The effective dose amount (in units of atoms/cm²) of impurity of the first conductivity type per unit area of the opposed region 12t in the X-Y plane is denoted by N2. The impurity concentration in the Y-axis direction of the pillar section 80 and the opposed region 12t is substantially constant. The two opposed regions 12t between the first gate trench 31p and the second gate trench 31q, and the pillar section 80 are regarded as one unit cell. The net dose amount of p-type impurity included in one pillar section 80 is N1. The net dose amount of n-type impurity included in the two opposed regions 12t is 2×N2. Here, the ratio of N1 to N2 satisfies the relation of e.g. 1≦(2×N2)/N1≦1.5. Thus, by increasing the n-type impurity concentration of the second semiconductor layer 12, the on-resistance can be reduced. For instance, the ratio is set to 1.15≦(2×N2)/N1≦1.5. Thus, the on-resistance can be reduced more appropriately. Here, the “effective dose amount” refers to the dose amount of impurity substantially contributing to conduction in the implanted dose amount except cancelation between acceptor and donor. For instance, the impurity concentration of the pillar section 80 can be adjusted by changing the dose amount of impurity and the width (length along the X-axis direction) of the pillar section 80.

Thus, by providing the pillar section 80, the opposed region 12t constituting an n-type pillar section forms a junction with the p-type pillar section 80 in the depth direction. Accordingly, the depletion layer of the pn junction extends more easily to the lateral direction (direction along the X-Y plane) of the substrate. This achieves a super-junction effect. In a typical super-junction structure, the effective dose amount of impurity included in the p-type pillar and the n-type pillar per unit volume needs to be balanced within approximately ±15%. However, in the structure according to this embodiment, even when the dose amount of the opposed region 12t is increased by 15% or more, the opposed region 12t can also be entirely depleted by the effect of the field plate structure. This synergistic effect of the super-junction structure and the field plate structure enables the enhancement of switching speed as well as the reduction of on-resistance by the increased concentration of the n-type pillar section.

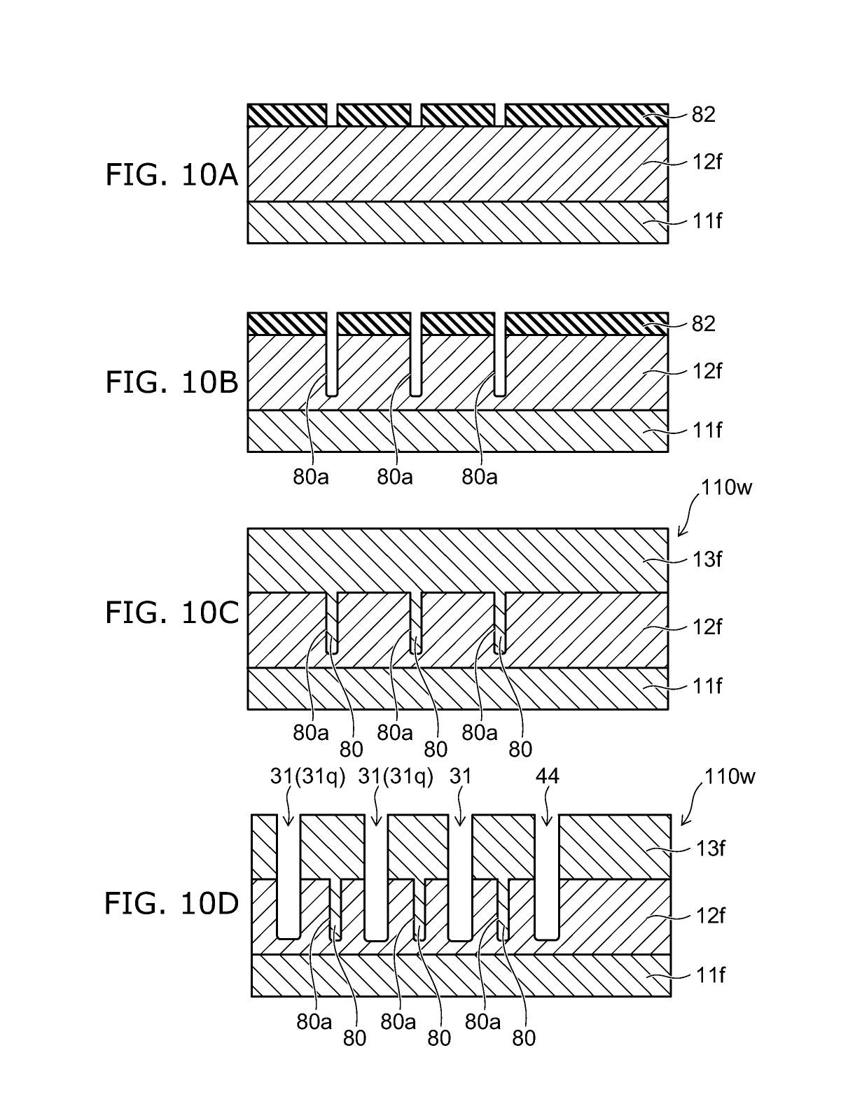

FIGS. 10A to 10D are schematic sectional views illustrating the sequential steps of a method for manufacturing a semiconductor device according to the second embodiment.

As shown in FIG. 10A, a second semiconductor film 12f is formed on a first semiconductor substrate 11f. Then, a mask 82 provided with a prescribed pattern is formed on the second semiconductor film 12f.

As shown in FIG. 10B, by etching processing, the pattern of the mask 82 is transferred to the second semiconductor film 12f to form a pillar trench 80a in the second semiconductor film 12f.

As shown in FIG. 10C, the mask 82 is removed. By epitaxial growth, a third semiconductor film 13f is formed on the second semiconductor film 12f. Part of the third semiconductor film 13f is embedded inside the pillar trench 80a. Thus, a pillar section 80 extending toward the first semiconductor substrate 11f is formed. In the case of forming a pillar section 80 in this manner, the concentration of p-type impurity included in the pillar section 80 is substantially equal to the concentration of p-type impurity included in the third semiconductor film 13f (third semiconductor layer 13).

As shown in FIG. 10D, a plurality of gate trenches 31 and a termination trench 44 are formed in the workpiece 110w. Here, the plurality of gate trenches 31 and the termination trench 44 are formed so that the pillar section 80 is located between the two nearest neighbor gate trenches 31. The formation of the plurality of gate trenches 31 includes forming a first gate trench 31p and a second gate trench 31q.

Subsequently, the processing described with reference to FIGS. 4A to 4C, 5A to 5D, and 6A to 6C is performed. Thus, the semiconductor device 120 is formed.

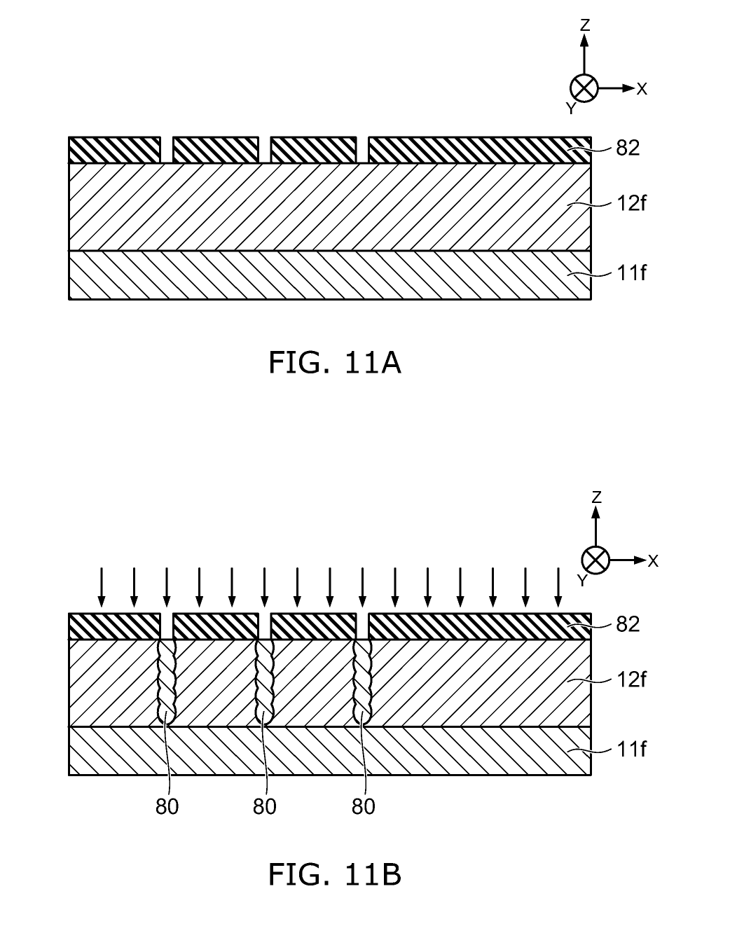

FIGS. 11A and 11B are schematic sectional views illustrating the sequential steps of an alternative method for manufacturing a semiconductor device according to the second embodiment.

As shown in FIG. 11A, a second semiconductor film 12f is formed on a first semiconductor substrate 11f. Then, a mask 82 provided with a prescribed pattern is formed on the second semiconductor film 12f.

As shown in FIG. 11B, ion implantation is performed. Thus, in conformity with the pattern of the mask 82, the second semiconductor film 12f is selectively doped with p-type impurity to form a pillar section 80 in the second semiconductor film 12f. On the second semiconductor film 12f with the pillar section 80 formed therein, a third semiconductor film 13f is formed by epitaxial growth. Subsequently, as described with reference to FIG. 10D, gate trenches 31 are formed. Then, the processing described with reference to FIGS. 4A to 4C, 5A to 5C, and 6A to 6C is performed. Thus, the semiconductor device 120 is formed. Thus, the pillar section 80 may be formed by ion implantation. In the case of forming a pillar section 80 in this manner, the concentration of p-type impurity included in the pillar section 80 can be set to an arbitrary value independently of the third semiconductor film 13f (third semiconductor layer 13).

According to the embodiments, a semiconductor device having low on-resistance and a method for manufacturing the same are provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

The embodiments of the invention have been described above with reference to examples. However, the embodiments of the invention are not limited to these examples. For instance, any specific configurations of various components such as the first semiconductor layers, second semiconductor layers, third semiconductor layers, fourth semiconductor layers, first main electrodes, second main electrodes, gate trenches, gate insulating films, gate electrodes, device regions, termination regions, insulating sections, field plate insulating films, field plate electrodes, and pillar sections included in the semiconductor devices are encompassed within the scope of the invention as long as those skilled in the art can similarly practice the invention and achieve similar effects by suitably selecting such configurations from conventionally known ones.

Further, any two or more components of the specific examples may be combined within the extent of technical feasibility and are included in the scope of the invention to the extent that the purport of the invention is included.

Moreover, all semiconductor devices and methods for manufacturing same practicable by an appropriate design modification by one skilled in the art based on the semiconductor devices and the methods for manufacturing same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, comprising:
forming a workpiece by forming a second semiconductor film on a major surface of a first semiconductor substrate having a first conductivity type, the second semiconductor film having a lower impurity concentration than the first semiconductor substrate, and by forming a third semiconductor film having a second conductivity type on the second semiconductor film by epitaxial growth, the workpiece including the first semiconductor substrate, the second semiconductor film, and the third semiconductor film and having a device region and a termination region surrounding the device region in a plane parallel to the major surface;
forming a gate trench penetrating through the third semiconductor film to part of the second semiconductor film in the device region, and a termination trench penetrating through the third semiconductor film to part of the second semiconductor film at a boundary between the device region and the termination region;
forming a first insulating layer on an inner wall surface of the gate trench and the termination trench;
forming a field plate electrode in a portion of the gate trench below the third semiconductor film by embedding a conductive material in a remaining space in the gate trench;
removing a portion of the first insulating layer above the field plate electrode;
forming a second insulating layer above the field plate electrode in the gate trench and on the inner wall surface of the gate trench above the field plate electrode, and forming a gate electrode by embedding a conductive material in a remaining space in the gate trench; and
selectively doping an upper portion of the device region of the third semiconductor film with impurity of the first conductivity type.

2. The method according to claim 1, wherein
the forming a second semiconductor film includes forming a pillar trench extending along a first direction parallel to the major surface in the second semiconductor film in the device region,
the forming a third semiconductor film includes forming a pillar section extending toward the first semiconductor substrate in the third semiconductor film by embedding the third semiconductor film inside the pillar trench, and
the forming a gate trench includes forming first and second gate trenches extending along the first direction and spaced from the pillar section in a second direction parallel to the major surface and perpendicular to the first direction, the pillar section being placed between the first gate trench and the second gate trench.

3. The method according to claim 1, wherein
the forming a workpiece includes, after forming the second semiconductor film, forming a pillar section extending toward the first semiconductor substrate by selectively doping a portion of the device region of the second semiconductor film with impurity of the second conductivity type, and
the forming a gate trench includes forming first and second gate trenches extending along the first direction and spaced from the pillar section in a second direction parallel to the major surface and perpendicular to the first direction, the pillar section being placed between the first gate trench and the second gate trench.
